(19) United States
(12) Patent Application Publication
(10) Pub. No.: US 2024/0143876 A1
(43) Pub. Date: May 2, 2024

(54) SIMULATION METHOD AND SIMULATION DEVICE

(71) Applicant: Samsung Electronics Co., Ltd., Suwon-si (KR)

(72) Inventors: Jichull Jeong, Suwon-si (KR); Taehyun Kim, Suwon-si (KR); Hyunjoong Kim, Suwon-si (KR); Euihyun Cheon, Suwon-si (KR)

(21) Appl. No.: 18/462,702

(22) Filed: Sep. 7, 2023

(30) Foreign Application Priority Data
Oct. 26, 2022 (KR) 10-2022-0139664

(51) Int. Cl. G06F 30/27; G06N 3/092

(52) U.S. Cl. CPC G06F 30/27; G06N 3/092; H03K 19/20

(57) ABSTRACT

A simulation method and a simulation device are disclosed. A simulation method according to the inventive concept is provided. A simulation method of the inventive concept may include obtaining an initial state variable and an initial reward variable detected from the semiconductor device, training an agent to output a first action variable of a reinforcement learning model based on the initial state variable and the initial reward variable; and generating a first state variable of the reinforcement learning model and generating a first reward variable, based on the first action variable, wherein the first reward variable includes a skew reward variable for rewarding a skew occurring in the semiconductor device and a duty reward variable for rewarding a duty error rate of an output signal output from the semiconductor device.

### CROSS-REFERENCE TO RELATED APPLICATION

This application is based on and claims priority under 35 U.S.C. § 119 to Korean Patent Application No. 10-2022-0139664, filed on Oct. 26, 2022, in the Korean Intellectual Property Office, the disclosure of which is incorporated by reference herein in its entirety.

### BACKGROUND

The inventive concept relates to a memory device, and more specifically, to an apparatus and method for controlling skew and duty error rate based on reinforcement learning.

A semiconductor device includes an integrated circuit for distributing signals, for example, signals provided from a host to various internal circuit configurations. An integrated circuit typically includes digital functions, analog functions, mixed signal functions, and radio frequency functions embedded on a single chip substrate. Integrated circuits typically include hardware (e.g., microprocessors, microcontrollers, etc.) and also the necessary software to control the functionality and implementation of the hardware. Because an integrated circuit receives external signals and distributes them to each of the input/output terminals, power consumption may be high and problems, such as skew in a transmission process, may occur.

### SUMMARY

The inventive concept, as manifested in one or more embodiments thereof, provides a simulation apparatus and method for simultaneously rewarding skew and duty error rates (or other signal timing issues) in a semiconductor device and/or system.

According to an aspect of the inventive concept, there is provided a simulation method including obtaining an initial state variable and an initial reward variable detected from the semiconductor device, training an agent to output a first action variable of a reinforcement learning model based on the initial state variable and the initial reward variable; and generating a first state variable of the reinforcement learning model and generating a first reward variable, based on the first action variable, wherein the first reward variable may include a skew reward variable for rewarding a skew occurring in the semiconductor device and a duty reward variable for rewarding a duty error rate of an output signal output from the semiconductor device.

According to another aspect of the inventive concept, there is provided a simulation device including a memory for storing instructions; and at least one processor configured to communicate with the memory and to simulate a reinforcement learning model by executing the instructions, wherein the at least one processor obtains the detected initial state variable and the initial reward variable, trains an agent to output a first action variable of a reinforcement learning model based on the detected initial state variable and the initial reward variable, and generates a first state variable and a first reward variable of the reinforcement learning model based on the first action variable, and the first reward variable includes a skew reward variable that rewards skew and a duty reward variable that rewards a duty error rate.

According to another aspect of the inventive concept, there is provided a simulation method including reinforcement learning model, the simulation method including obtaining detected initial state variables, initial skew reward variables, and initial duty reward variables, training an agent to output a first action variable of a reinforcement learning model based on the detected initial state variable, the initial skew reward variable, and the initial duty reward variable, and generating a first state variable, a first skew reward variable, and a first duty reward variable of the reinforcement learning model based on the first action variable, wherein the first skew reward variable includes a first skew variable and a second skew variable, and the first duty reward variable includes a first duty variable and a second duty variable.

Techniques of the present inventive concept can provide substantial beneficial technical effects. By way of example only and without limitation, a simulation device and/or method configured to simultaneously reward skew and duty error rates, according to one or more embodiments of the invention, may provide one or more of the following advantages:
improves an operation and efficiency of memory devices as described herein by reducing simulation costs;
reduces the need for large labeled datasets compared to other training methodologies;
reduces power consumption in memory devices;
avoids the need for retraining by adapting to new system environments automatically on the fly based on skew and duty error rate information.

### BRIEF DESCRIPTION OF THE DRAWINGS

Embodiments of the inventive concept will be more clearly understood from the following detailed description taken in conjunction with the accompanying drawings in which:

FIG. 1 is a block diagram illustrating a system including a reinforcement learning model, according to an embodiment;

FIG. 2 is a block diagram illustrating a reinforcement learning model according to an embodiment;

FIG. 3 is a circuit diagram showing a C2C (CML to CMOS) circuit in which a CML (current mode logic) circuit and a CMOS circuit of a simulation device are coupled to each other, according to an embodiment;

FIG. 4 is a circuit diagram showing the CML circuit of FIG. 3;

FIG. 5 is a circuit diagram illustrating the CMOS circuit of FIG. 3;

FIG. 6 is a flowchart illustrating a method of controlling skew and duty error rate, according to an embodiment;

FIG. 7 is a flowchart illustrating a method of controlling a duty error rate, according to an embodiment; and

FIG. 8 is a block diagram illustrating a simulation system according to an embodiment.

### DETAILED DESCRIPTION OF THE EMBODIMENTS

Hereinafter, embodiments of the inventive concept are described in detail with reference to the accompanying drawings.

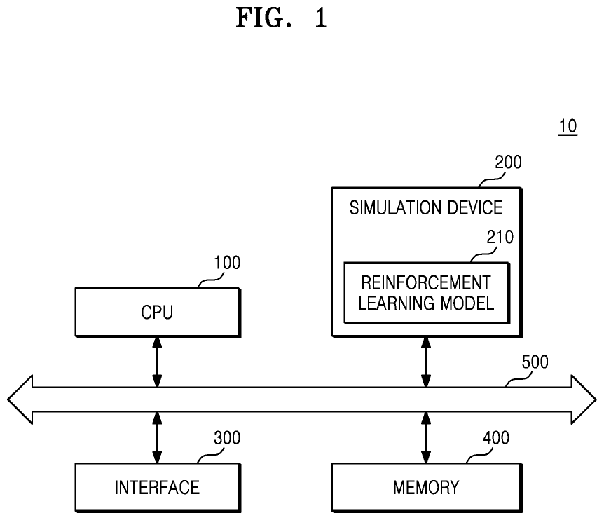

FIG. 1 is a block diagram illustrating a system including a reinforcement learning model, according to an embodiment. Reinforcement learning, in general, is a machine learning training methodology based on rewarding desired actions and/or punishing undesired actions. By simultaneously rewarding skew and duty error rates, techniques according to the inventive concepts described herein may improve an operation and efficiency of memory devices and/or systems such as by reducing simulation costs and/or power consumption in the devices and/or systems, among other technological benefits and improvements. Embodiments of the present disclosure therefore may involve correcting timing issues in a semiconductor device using a reinforcement training model that facilitates correction “on the fly” by rewarding optimal skew and duty error rates in the device. As may be used herein, the term “duty error” is intended to refer to, and be used synonymously with, the terms “duty cycle” and “data error rate.”

Referring to FIG. 1, a system 10 may include a central processing unit (CPU) 100, a simulation device 200, an interface 300, a memory 400, and a bus 500. The system 10 may further include an input/output module, a security module, a power control device, and the like, and may further include various types of processors (not explicitly shown, but implied). The system 10 may be a data processing system that includes a reinforcement learning model 210.

According to some embodiments, components of the system 10 (e.g., some of the CPU 100, the memory 400, the interface 300, and the simulation device 200) may be formed on a single semiconductor chip. For example, the system 10 may be implemented as a system-on chip (SoC). The components of the system 10 may communicate with each other via the bus 500.

The CPU 100 controls the overall operation of the system 10. The CPU 100 may include a single processing core or may include a plurality of processing cores (multi-cores). The CPU 100 may process or execute programs and/or data stored in a storage area, such as the memory 400. For example, the CPU 100 may control the system 10 required due to the execution of application programs.

Although not explicitly shown, the system 10 may further include a graphics processing unit (GPU). The GPU accelerates the computational operations of the system 10. The GPU may include multi-cores, be operated by being connected to other GPUs through a CPU, peripheral component interconnect express (PCI-e), and NVLINK, and accelerate general-purpose computational operations through a compute unified device architecture (CUDA). The GPU may process or execute programs and/or data stored in a storage area, such as the memory 400.

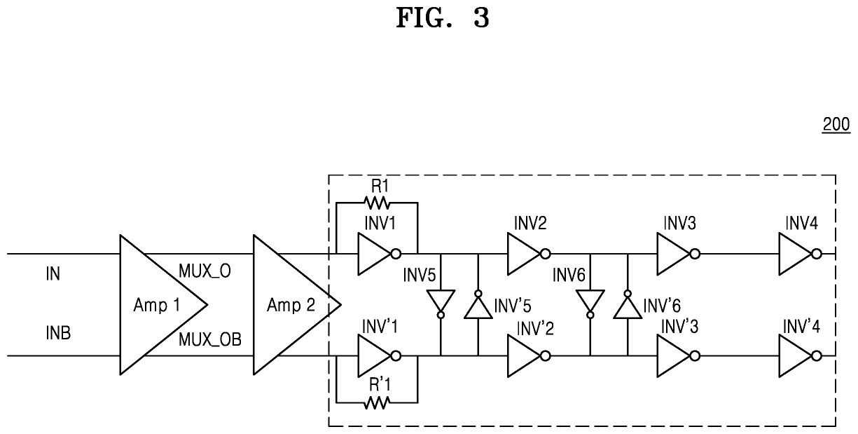

Although not explicitly shown, the system 10 may further include a memory controller. As a host, the memory controller may control the memory 400 in response to processing results of the CPU 100 and/or the GPU. For example, the memory controller may provide a clock signal and a command/address signal to the memory 400 and exchange data with the memory 400. As will be described below with reference to FIG. 3, logic circuits of the simulation device 200 may be classified into a current mode logic (CML) circuit and a complementary metal-oxide semiconductor (CMOS) circuit based on signal processing methods.

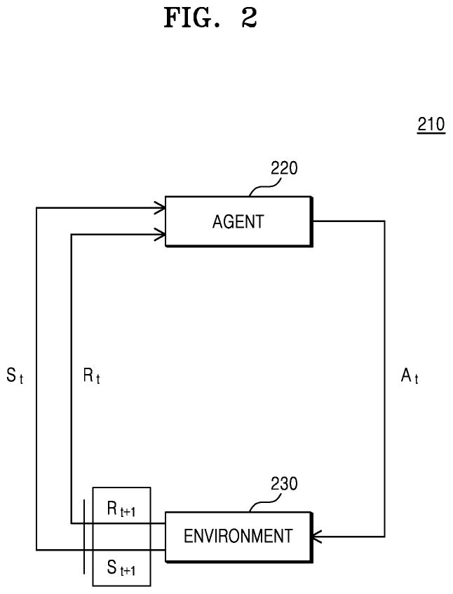

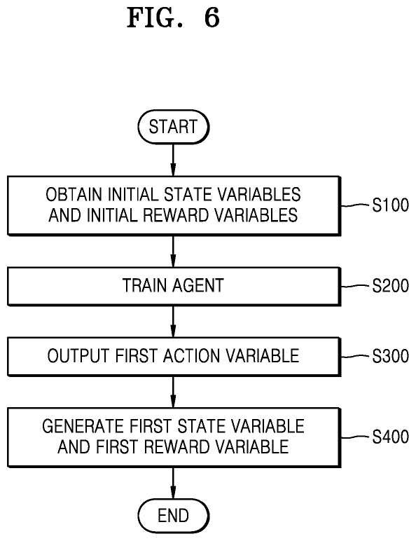

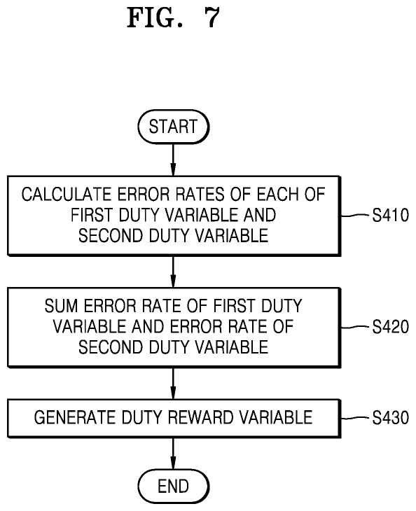

With continued reference to FIG. 2, the simulation device 200 may include a reinforcement learning model 210. The reinforcement learning model 210 may control skew and duty error rates based on reinforcement learning. The reinforcement learning model may be model-free machine learning, and as described below with reference to FIG. 2, in a reinforcement learning model, an agent may be trained to perform an action to maximize a reward in an environment. An optimal skew and duty error rate may be derived from the reinforcement learning model 210. Accordingly, a device in which the reinforcement learning model 210 is implemented (e.g., the simulation device 200 of FIG. 1) may be trained to determine an optimal skew and duty error rate considering both the skew and the duty error rate. An example of the operation of the agent and the environment is described below with reference to FIGS. 6 and 7. Accordingly, the simulation device 200 may simultaneously reward an optimal skew and duty error rate by performing reinforcement learning.

The memory 400 may store programs and/or data used in the system 10. The memory 400 may be dynamic random access memory (DRAM) but is not limited thereto. The memory 400 may include at least one of volatile memory and nonvolatile memory. The nonvolatile memory includes read only memory (ROM), programmable ROM (PROM), electrically programmable ROM (EPROM), electrically erasable and programmable ROM (EEPROM), flash memory, phase-change RAM (PRAM), magnetic RAM (MRAM), resistive RAM (RRAM), ferroelectric RAM (FRAM), and the like. The volatile memory includes DRAM, static RAM (SRAM), synchronous DRAM (SDRAM), and the like. In an embodiment, the memory 400 may include at least one of a hard disk drive (HDD), a solid-state drive (SSD), a compact flash (CF) card, a secure digital (SD) card, a micro secure digital (micro-SD) card, a mini secure digital (Mini-SD) card, an extreme digital (xD) card, and a memory stick.

The interface 300 may receive simulation information generated by the system 10 and provide the received simulation information to the memory 400. The simulation device 200 may perform simulation for reinforcement learning using simulation information.

The simulation device 200 according to embodiments may simultaneously reward optimal skew and duty error rates, and may minimize simulation cost and power due to reinforcement learning.

FIG. 2 is a block diagram illustrating a reinforcement learning model according to an embodiment. As described above with reference to FIG. 1, the reinforcement learning model 210 may be used to determine skew and duty error rates of a memory or semiconductor device, and may be implemented in the simulation device 200 of FIG. 1.

Referring to FIG. 2, the reinforcement learning model 210 may include an agent 220 and an environment 230. In this specification, the reinforcement learning model 210 may be referred to as a reinforcement learning platform, the agent 220 may be referred to as an agent module or reinforcement learning agent, and the environment 230 may be referred to as an environment module or reinforcement learning environment. The agent 220 and the environment 230 may be implemented as hardware within a processor or as software running on the processor.

Here, the reinforcement learning model 210 refers to a learning technique that learns to select a better action later by continuously and repeatedly reflecting the changed state and reward depending on the action selected by the agent 220.

The agent 220 may receive a state variable S(t) and a reward variable R(t) from the environment 230, and may provide an action variable A(t) to the environment 230. The agent 220 may be trained to provide an action corresponding to the maximum reward in the state received from the environment 230. For example, the agent 220 may include a quality (Q)-table, and may learn by updating the Q-table based on the reward variable R(t) received from the environment 230. The Q-table may include a Q-value including a reward variable for each combination of state variables and action variables. The environment 230 may change the state variable S(t) by the action variable A(t), and may generate a reward variable R(t+1) based on the changed state variable S(t+1)

The state variable S(t) may include an initial state variable and a first state variable to a t-th state variable, and the reward variable R(t) may include an initial reward variable and a first reward variable to a t-th reward variable. The action variables A(t) may include first to t-th action variables. In this specification, each of the state variable S(t), the reward variable R(t), and the action variable A(t) may be referred to as a state, a reward, and an action, respectively.

For example, the agent 220 may receive an initial state variable and an initial action variable from the environment 230 and may provide a first action variable A(t) to the environment 230. The agent 220 may perform reinforcement learning based on the initial state variables and initial action variables received from the environment 230. The agent 220 may be trained to provide the action variable A(t) corresponding to a maximum reward variable R(t) in the state variable S(t). The agent 220 may output the first action variable through reinforcement learning. The environment 230 may receive the first action variable, change the initial state variable to the first state variable, and generate a first reward variable based on the changed first state variable.

Given the current state S(t) and the reward R(t) for the previous action A(t−1) from the environment 230, the agent 220 may determine the action A(t) such that the reward R(t) is further increased in the current state S(t). Then, the environment 230 may update the state S(t) to the next state S(t+1) depending on the action A(t) determined by the agent 220, and may determine the reward R(t+1) based on the updated state S(t+1).

In some embodiments, the environment 230 may generate a first state variable and a first reward variable based on the detected initial state S(0) and initial reward R(0). The agent 220 may also generate the action A(t) based on the state and Q-table provided from the environment 230. Accordingly, the agent 220 may be trained to determine an optimal skew and duty error rate considering both skew and duty error rates in a device (e.g., the simulation device 200 of FIG. 1) in which the reinforcement learning model 210 is implemented. An example of the operation of the agent 220 and the environment 230 is described below with reference to FIGS. 6 and 7.

FIG. 3 is a circuit diagram showing a CML-to-CMOS (C2C) conversion circuit in which a CML circuit and a CMOS circuit of a simulation device are coupled to each other.

Referring to FIG. 3, a simulation device 200 may include a first amplifier Amp 1, a second amplifier Amp 2, first to sixth inverters INV1 to INV6, and 1-1 to 6-1 inverters INV′1 to INV′6. Logic circuits of the simulation device 200 may be classified into a CML circuit and a CMOS circuit based on a signal processing method. For example, the first amplifier Amp 1 and the second amplifier Amp 2 may be CML circuits, and the first to sixth inverters INV1 to INV6 and the 1st-1 to 6th-1 inverters INV′1 to INV′6 may be a CMOS circuit.

The first amplifier Amp 1 may receive the first input signal IN, which may be non-inverted, and the first inverted input signal INB. The second amplifier Amp 2 may receive signals output from the first amplifier Amp 1. The second amplifier Amp 2 may receive the second input signal MUX_O, which may be non-inverted, and the inverted second input signal MUX_OB. Like the first amplifier Amp 1, the second amplifier Amp 2 may generate non-inverted and inverted output signals; these signals may be presented as inputs to the CMOS circuit.

The first inverter INV1 and the 1st-1 inverter INV′1 may be connected to a corresponding output terminal of the second amplifier Amp 2. The first inverter INV1 and the 1st-1 inverter INV′1 may receive one of the output signals of the second amplifier Amp 2 as an input. Each of the first inverter INV1 and the 1st-1 inverter INV′1 may be connected in parallel with a first resistor R1 and a 1st-1 resistor R′1, respectively. The second inverter INV2 and the 2nd-1 inverter INV′2 may be connected to respective output terminals of the 1st inverter INV1 and the 1st-1 inverter INV′1. The second inverter INV2 and the 2nd-1 inverter INV′2 may receive output signals of the first inverter INV1 and the 1st-1 inverter INV′1 as inputs. The third inverter INV3 and the 3rd-1 inverter INV′3 may be connected to respective output terminals of the second inverter INV2 and the 2nd-1 inverter INV′2. The third inverter INV3 and the 3rd-1 inverter INV′3 may receive respective output signals of the second inverter INV2 and the 2nd-1 inverter INV′2 as inputs. The fourth inverter INV4 and the 4th-1 inverter INV′4 may be connected to output terminals of the third inverter INV3 and the 3rd-1 inverter INV′3, respectively. The fourth inverter INV4 and the 4th-1 inverter INV′4 may receive respective output signals of the third inverter INV3 and the 3rd-1 inverter INV′3 as inputs. The fourth inverter INV4 and the 4th-1 inverter INV′4 may output a first skew variable signal representing a first skew variable and a second skew variable signal representing a second skew variable, a first duty variable signal representing a first duty variable, and a second duty variable signal representing a second duty variable.

The fifth inverter INV5 and 5th-1 inverter INV′5 may be connected in a back-to-back configuration as a latch or bistable element. Specifically, an input of the fifth inverter INV5 may be connected to an output terminal of the first inverter INV1, and a value output from the fifth inverter INV5 may be connected to an input terminal of the 2nd-1 inverter INV′2. An input of the 5th-1 inverter INV′5 may be connected to an output terminal of the 1st-1 inverter INV′1, and a value output from the 5th-1 inverter INV′5 may be connected to an input terminal of the second inverter INV2. Similarly, the sixth inverter INV6 and 6th-1 inverter INV′6 may be connected in a back-to-back configuration. Specifically, an input of the sixth inverter INV6 may be connected to an output terminal of the second inverter INV2, and a value output from the sixth inverter INV6 may be connected to an input terminal of the 3rd-1 inverter INV′3. An input of the 6th-1 inverter INV′6 may be connected to an output terminal of the 2nd-1 inverter INV′2, and a value output from the 6th-1 inverter INV′6 may be connected to an input terminal of the third inverter INV3.

As intended to be used herein, the term “skew” may refer broadly to a phase difference (e.g., 180° phase delay) between the first input IN and the inverted first input INB of the first amplifier Amp 1 or may refer to a skew generated in a semiconductor device. A skew variable may include the first skew variable and the second skew variable. A duty variable may refer to a difference between data errors of the first input IN and the inverted first input INB of the first amplifier Amp 1, and may include the first duty variable and the second duty variable. A duty error rate may be an absolute value for a value excluding 50% from each duty variable. For example, a duty error rate ε of the first duty variable may be calculated as in Equation 1 below. In Equation 1, duty 1 may mean the first duty variable.

ε=|duty 1−50%| [Equation 1]

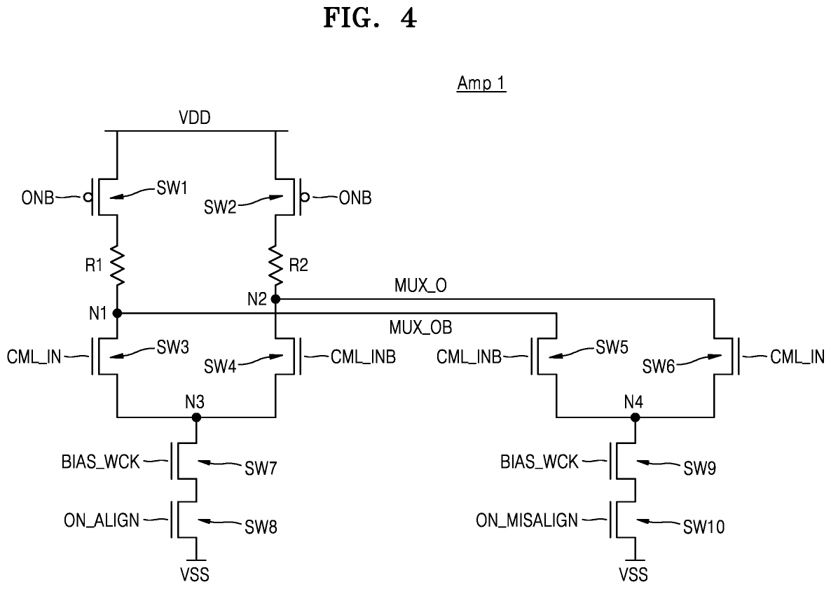

FIG. 4 is a circuit diagram showing the CML circuit of FIG. 3.

In detail, FIG. 4 is a circuit diagram showing the configuration of the first amplifier Amp 1, which in some embodiments may be implemented as an operational amplifier (e.g., a differential input, differential output operational amplifier), as shown.

The first amplifier Amp 1 may include first to tenth switches SW1 to SW10, a first resistor R1, and a second resistor R2. Each of at least a subset of the switches SW1 to SW10 may be implemented as n-channel or p-channel metal-oxide semiconductor (NMOS or PMOS) transistors, as shown. Control signals ONB, CML_IN, CML_INB, BIAS_WCK, ON_ALIGN, and ON_MISALIGN may be applied to the first amplifier Amp 1, and at least some of the control signals may be generated by a memory controller or a host.

One end of the first switch SW1 may receive a first voltage VDD (e.g., the first voltage may be a power supply voltage), and the other end of the first switch SW1 may be connected to the first resistor R1. One end of the second switch SW2 may receive the first voltage VDD, and the other end of the second switch SW2 may be connected to the second resistor R2. Gates of the first switch SW1 and the second switch SW2 may receive a switch control signal ONB. The first switch SW1 and the second switch SW2 may be turned on or turned off in response to the switch control signal ONB. For example, the first switch SW1 and the second switch SW2, being PMOS transistors in this illustrative embodiment, may be turned on depending on the switch control signal ONB having a low level (e.g., VSS), and may be turned off depending on to the switch control signal ONB having a high level (e.g., VDD).

One end of the first resistor R1 may be connected to the first switch SW1 and the other end of the first resistor R1 may be connected to a first node N1. One end of the second resistor R2 may be connected to the second switch SW2 and the other end of the second resistor R2 may be connected to a second node N2. The first and second resistors R1, R2, and the first and second switches SW1, SW2 form an active load of the first amplifier Amp 1.

One end of the third switch SW3 may be connected to the first node N1 and the other end of the third switch SW3 may be connected to a third node N3. One end of the sixth switch SW6 may be connected to the second node N2 and the other end the sixth switch SW6 may be connected to a fourth node N4. Gates of the third switch SW3 and the sixth switch SW6 may receive an input control signal CML_IN. The third switch SW3 and the sixth switch SW6 may be turned on or off in response to the input control signal CML_IN. For example, the third switch SW3 and the sixth switch SW6, which may be NMOS transistors in this illustrative embodiment, may be turned on depending on the input control signal CML_IN having a high level, and may be turned off depending on the input control signal CML_IN having a low level.

One end of the fourth switch SW4 may be connected to the second node N2 and the other end of the fourth switch SW4 may be connected to the third node N3. One end of the fifth switch SW5 may be connected to the first node N1 and the other end of the fifth switch SW5 may be connected to the fourth node N4. Gates of the fourth switch SW4 and the fifth switch SW5 may receive an inversion input control signal CML_INB. The fourth switch SW4 and the fifth switch SW5 may be turned on or off in response to the inverting input control signal CML_INB. Each of the input control signal CML_IN and the inverted input control signal CML_INB may be complementary to each other. For example, the third switch SW3 and the sixth switch SW6, which may be NMOS transistors in this illustrative embodiment, may be turned off depending on the input control signal CML_IN having a low level, and may be turned on depending on the input control signal CML_IN having a high level. When the fourth switch SW4 and the fifth switch SW5 are turned on, the third switch SW3 and the sixth switch SW6 may be turned off, and when the fourth switch SW4 and the fifth switch SW5 are turned off, the third switch SW3 and the sixth switch SW6 may be turned on. The third switch SW3 and the sixth switch SW6, and the fourth switch SW4 and the fifth switch SW5 may be turned on or off in a complementary manner. The fourth and fifth switches SW4 and SW5 may be NMOS transistors. The third, fourth, fifth and sixth switches SW3, SW4, SW5, SW6, coupled with the active load, form a differential input stage of the first amplifier Amp 1.

One end of the seventh switch SW7 may be connected to the third node N3, and the other end of the seventh switch SW7 may be connected to the eighth switch SW8. A gate of the seventh switch SW7 may receive a first control signal BIAS_WCK. The seventh switch SW7 may be turned on or off in response to the first control signal BIAS_WCK. For example, the seventh switch SW7, which may be an NMOS transistor in this illustrative embodiment, may be turned off depending on the first control signal BIAS_WCK having a low level, and may be turned on depending on the first control signal BIAS_WCK having a high level.

One end of the eighth switch SW8 may be connected to the seventh switch SW7, and the other end of the eighth switch SW8 may receive a second voltage VSS (e.g., the second voltage may be a ground voltage). A gate of the eighth switch SW8 may receive a second control signal ON_ALIGN. The eighth switch SW8 may be turned on or off in response to the second control signal ON_ALIGN. For example, the eighth switch SW8, which may be an NMOS transistor in this illustrative embodiment, may be turned on depending on the second control signal ON_ALIGN having a high level, and may be turned off depending on the second control signal ON_ALIGN having a low level.

One end of the ninth switch SW9 may be connected to the fourth node N4 and the other end of the ninth switch SW9 may be connected to the tenth switch SW10. The ninth switch SW9 may be turned on or off in response to the first control signal BIAS_WCK. For example, the ninth switch SW9, which may be an NMOS transistor in this illustrative embodiment, may be turned off depending on the first control signal BIAS_WCK having a low level, and may be turned on depending on the first control signal BIAS_WCK having a high level.

One end of the tenth switch SW10 may be connected to the ninth switch SW9 and the other end of the tenth switch SW10 may receive the second voltage VSS. The gate of the tenth switch SW10 may receive a third control signal ON_MISALIGN. The tenth switch SW10 may be turned on or turned off in response to the third control signal ON_MISALIGN. The third control signal ON_MISALIGN may be a signal complementary to or inverted from the second control signal ON_ALIGN, but is not limited thereto. For example, the tenth switch SW10, which may be an NMOS transistor in this illustrative embodiment, may be turned off depending on the third control signal ON_MISALIGN having a low level, and may be turned on depending on the third control signal ON_MISALIGN having a high level. When the tenth switch SW10 is turned on, the eighth switch SW8 may be turned off, and when the tenth switch SW10 is turned off, the eighth switch SW8 may be turned on. The tenth switch SW10 and the eighth switch SW8 may be turned on or turned off complementarily.

The first node N1 may be connected to the first input terminal of the second amplifier Amp 2, and the second node N2 may be connected to the second input terminal of the second amplifier Amp 2.

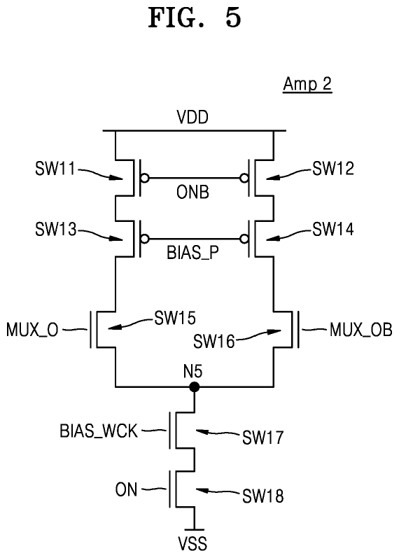

FIG. 5 is a circuit diagram illustrating the CMOS circuit of FIG. 3. In detail, FIG. 5 is a circuit diagram showing a configuration of the second amplifier Amp 2, according to one or more embodiments.

Referring to FIG. 5, the second amplifier Amp 2 may include first to eighth switches SW11 to SW18.

Control signals ONB, BIAS_P, MUX_O, MUX_OB, BIAS_WCK, and ON may be applied to the second amplifier Amp 2, and at least some of the control signals may be generated by a memory controller or a host.

One end of the first switch SW11 may receive a first voltage VDD, and the other end of the first switch SW11 may be connected to the third switch SW13. One end of the second switch SW12 may receive the first voltage VDD, and the other end of the second switch SW12 may be connected to the fourth switch SW14. Gates of the first switch SW11 and the second switch SW12 may receive the switch control signal ONB. The first switch SW11 and the second switch SW12 may be turned on or off in response to the switch control signal ONB. For example, the first switch SW11 and the second switch SW12, which may be PMOS transistors in this illustrative embodiment, may be turned on depending on the switch control signal ONB having a low level, and may be turned off depending on the switch control signal ONB having a high level.

One end of the third switch SW13 may be connected to the first switch SW11 and the other end of the third switch SW13 may be connected to the fifth switch SW15. One end of the fourth switch SW14 may be connected to the second switch SW12 and the other end of the fourth switch SW14 may be connected to the sixth switch SW16. Gates of the third switch SW13 and the fourth switch SW14 may receive the first control signal BIAS_P. The third switch SW13 and the fourth switch SW14 may be turned on or off in response to the first control signal BIAS_P. For example, the third switch SW13 and the fourth switch SW14, which may be PMOS transistors in this illustrative embodiment, may be turned on depending on the first control signal BIAS_P having a low level, and may be turned off depending on the first control signal BIAS_P having a high level. The first, second, third and fourth switches SW11, SW12, SW13, SW14, may form a cascode active load of the second amplifier Amp 2.

One end of the fifth switch SW15 may be connected to the third switch SW13 and the other end of the fifth switch SW15 may be connected to a first node N5. A gate of the fifth switch SW15 may receive the input control signal MUX_O. The fifth switch SW15 may be turned on or off in response to the input control signal MUX_O. For example, the fifth switch SW15, which may be an NMOS transistor in this illustrative embodiment, may be turned on depending on the input control signal MUX_O having a high level, and may be turned off depending on the input control signal MUX_O having a low level.

One end of the sixth switch SW16 may be connected to the fourth switch SW14 and the other end of the sixth switch SW16 may be connected to the first node N5. A gate of the sixth switch SW16 may receive an inverted input control signal MUX_OB. The sixth switch SW16 may be turned on or off in response to the inverted input control signal MUX_OB. The inverted input control signal MUX_OB and the input control signal MUX_O may be complementary or inverted signals. For example, the sixth switch SW16, which may be an NMOS transistor in this illustrative embodiment, may be turned off depending on the inverted input control signal MUX_OB having a low level, and may be turned on depending on the inverted input control signal MUX_OB having a high level. When the sixth switch SW16 is turned on, the fifth switch SW15 may be turned off, and when the sixth switch SW16 is turned off, the fifth switch SW15 may be turned on. The fifth switch SW15 and the sixth switch SW16 may be turned on or turned off complementarily. The fifth and sixth switches SW15, SW16 may form a differential input pair of the second amplifier Amp 2.

One end of the seventh switch SW17 may be connected to the first node N5, and the other end of the seventh switch SW17 may be connected to the eighth switch SW18. A gate of the seventh switch SW17 may receive a second control signal BIAS_WCK. The seventh switch SW17 may be turned on or off in response to the second control signal BIAS_WCK. For example, the seventh switch SW17, which may be an NMOS transistor in this illustrative embodiment, may be turned off depending on the second control signal BIAS_WCK having a low level, and may be turned on depending on the second control signal BIAS_WCK having a high level.

One end of the eighth switch SW18 may be connected to the seventh switch SW17, and the other end of the eighth switch SW18 may receive a second voltage VSS. A gate of the eighth switch SW18 may receive the inverted switch control signal ON. The inverted switch control signal ON and the switch control signal ONB may be complementary or inverted signals. The eighth switch SW18 may be turned on or turned off in response to the inverted switch control signal ON. For example, the eighth switch SW18, which may be an NMOS transistor in this illustrative embodiment, may be turned on depending on the inverted switch control signal ON having a high level, and may be turned off depending on the inverted switch control signal ON having a low level. The seventh and eighth switches SW17, SW18 may form a cascode bias source of the second amplifier Amp 2.

FIG. 6 is a flowchart illustrating a method of controlling skew and duty error rate according to an embodiment. FIG. 7 is a flowchart illustrating a method of controlling a duty error rate, according to an embodiment.

As shown in FIG. 6, the method for controlling the skew and duty error rate may include a plurality of operations S100, S200, S300, and S400. In some embodiments, the method of FIG. 6 may be performed by the simulation device 200 of FIG. 1. Hereinafter, FIG. 6 is described with reference to FIG. 1, and it is assumed that the reinforcement learning model 210 of FIG. 1 includes the agent 220 and the environment 230 of FIG. 2.

Referring to FIG. 6, in operation S100, initial state variables and initial reward variables may be obtained. For example, the agent 220 shown in FIG. 2 may obtain initial state variables and initial action variables from the environment 230.

In operation S200, an agent of the reinforcement learning model may be trained based on the initial state variable and the initial reward variable obtained in operation S100. In operation S300, the trained agent may output a first action variable. For example, the agent 220 shown in FIG. 2 may perform reinforcement learning based on the initial state variables and initial action variables received from the environment 230. The agent 220 may be trained to provide the action variable A(t) corresponding to a maximum reward variable R(t) in the state variable S(t). The agent 220 may output the first action variable through reinforcement learning. That is, given the current state S(t) and the reward R(t) for the previous action A(t−1) from the environment 230, the agent 220 may determine the action A(t) such that the reward R(t) is further increased in the current state S(t).

In operation S400, based on the first action variable, a first state variable and a first reward variable of the reinforcement learning model may be generated. For example, the environment 230 shown in FIG. 2 may receive the first action variable to change the initial state variable into the first state variable, and may generate the first reward variable based on the changed first state variable. That is, the environment 230 may update the state S(t) to the next state S(t+1) based on the action A(t) determined by the agent 220, and may determine the reward R(t+1) based on the updated state S(t+1).

For example, generating the first reward variable in operation S400 may include generating a skew reward variable and generating a duty reward variable. The skew reward variable may include a first skew variable skew 1 and a second skew variable skew 2, and the duty reward variable may include a first duty variable duty 1 and a second duty variable duty 2.

Generating the skew reward variable may include summing the first skew variable skew 1 and the second skew variable skew 2.

Generating the duty reward variable may include calculating the duty reward variable based on the first duty variable duty 1 and the second duty variable duty 2.

According to the simulation method according to the embodiment, by performing reinforcement learning, an optimal skew and duty error rate may be simultaneously rewarded, and simulation cost and power due to reinforcement learning may be minimized.

As shown in FIG. 7, The method of generating the first reward variable may include a plurality of operations S410, S420, and S430. In detail, the flowchart of FIG. 7 shows an example of operation S400 of FIG. 6 for generating the first state variable and the first reward variable of the reinforcement learning model. As described above with reference to FIG. 6, generating the first reward variable may include generating a duty reward variable. In some embodiments, the method of FIG. 7 may be performed by the simulation device 200 of FIG. 1. Hereinafter, FIG. 7 is described with reference to FIGS. 1 and 6, and it is assumed that the reinforcement learning model 210 of FIG. 1 includes the agent 220 and the environment 230 of FIG. 2.

Referring to FIG. 7, as an example for generating the first reward variable, in operation S410, error rates of each of the first duty variable duty 1 and the second duty variable duty 2 may be calculated. For example, generating the duty reward variable may include calculating the duty reward variable based on the first duty variable duty 1 and the second duty variable duty 2. Calculating the duty reward variable may include calculating an error rate of each of the first duty variable duty 1 and the second duty variable duty 2. Here, the operation of calculating the error rate may mean an operation of excluding 50% from each duty variable. For example, the error rate may be calculated by the formulas |first duty variable duty 1−50%| and |second duty variable duty 2−50%|.

In operation S420, the error rate of the first duty variable duty 1 may be summed with the error rate of the second duty variable duty 2. For example, calculating the duty reward variable may include adding an error rate of the first duty variable duty 1 to an error rate of the second duty variable duty 2.

In operation S430, the duty reward variable may be generated. In some embodiments, generating the first reward variable may include generating the first reward variable based on the minimum value of the skew reward variable and the minimum value of the duty reward variable. For example, the first reward variable may be a sum of the minimum value of the skew reward variable that is a sum of the first skew variable skew 1 and the second skew variable skew 2 and the minimum value of the duty reward variable that is a sum of the first duty variable duty 1 and the second duty variable duty 2.

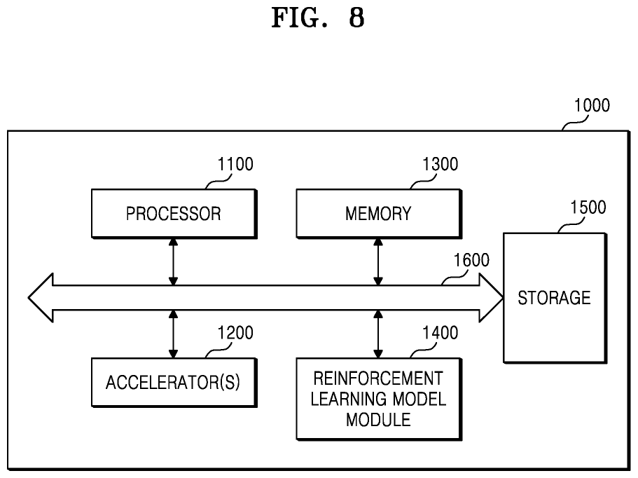

FIG. 8 is a block diagram illustrating a simulation system according to an embodiment. As described above with reference to the drawings, a simulation system 1000 may implement a reinforcement learning model (e.g., 210 of FIGS. 1 and 2), and may use the reinforcement learning model 210 to determine optimal skew and duty error rates.

As shown in FIG. 8, the simulation system 1000 may include at least one processor 1100, at least one accelerator 1200, a memory 1300, a reinforcement learning model module 1400, a storage 1500, and a bus 1600. Although only one processor 1100 is shown in FIG. 8, more processors may be provided. The processor 1100, the memory 1300, the reinforcement learning model module 1400, and the storage 1500 may communicate with each other through the bus 1600.

At least one processor 1100 may execute a series of instructions. For example, at least one processor 1100 may execute instructions stored in the memory 1300 or the storage 1500. In addition, at least one processor 1100 may load instructions from the memory 1300 or the storage 1500 into the internal memory and execute the loaded instructions. In some embodiments, at least one processor 1100 may perform at least some of the operations described above with reference to the drawings by executing instructions.

The accelerator 1200 may be designed to perform predefined motions at a high speed. For example, the accelerator 1200 may load data stored in the memory 1300 and/or the storage 1500, and may store data generated by processing the loaded data in the memory 1300 and the storage 1500. In some embodiments, the accelerator 1200 may perform at least some of the operations described above with reference to the drawings at a high speed.

The memory 1300 is a non-transitory storage device and may be accessed through the bus 1600 by at least one processor 1100. In some embodiments, the memory 1300 may include volatile memory, such as DRAM and SRAM, and may include non-volatile memory, such as flash memory, RRAM, etc. In some embodiments, the memory 1300 may store instructions and data for performing at least some of the operations described above with reference to the drawings.

The term ‘module’ as used herein refers to software or hardware components, such as field programmable gate arrays (FPGAs) or application specific integrated circuits (ASICs), and the ‘module’ performs certain roles. However, the ‘module’ is not limited to software or hardware. The ‘module’ may be configured to reside on an addressable storage medium and may be configured to reproduce one or more processors. Thus, as an example, the ‘module’ may include components, such as software components, object-oriented software components, class components, and task components, processes, functions, properties, procedures, subroutines, segments of program code, drivers, firmware, microcode, circuits, data, databases, data structures, tables, arrays, and variables. Functionality provided within components and ‘modules’ may be combined into a smaller number of components and ‘modules’ or further separated into additional components and ‘modules’.

The reinforcement learning model module 1400 may control skew and duty error rates based on reinforcement learning. The reinforcement learning model module 1400 allows an agent to be trained to perform an action to maximize a reward in an environment. The reinforcement learning model module 1400 may store data required for simulation of the reinforcement learning model using the processor 1100. Data required for simulation may be stored in the storage 1500. The reinforcement learning model module 1400 may simultaneously reward an optimal skew and duty error rate by performing reinforcement learning, and may minimize simulation cost and power due to reinforcement learning.

The storage 1500 is a non-temporary storage device, and stored data may not be lost even if power supply thereto is cut off. For example, the storage 1500 may include a semiconductor memory device, such as a flash memory, or may include any storage medium, such as a magnetic disk or an optical disk. In some embodiments, the storage 1500 may store instructions, programs, and/or data for performing at least some of the operations described above with reference to the drawings.

While the inventive concept has been particularly shown and described with reference to embodiments thereof, it will be understood that various changes in form and details may be made therein without departing from the spirit and scope of the following claims.

What is claimed is:

1. A processor-implemented simulation method comprising:
obtaining an initial state variable and an initial reward variable detected from a semiconductor device;
training an agent to output a first action variable of a reinforcement learning model based on the initial state variable and the initial reward variable;
generating, by at least one processor, a first state variable of the reinforcement learning model and generating a first reward variable, based on the first action variable; and
correcting at least one timing issue in the semiconductor device as a function of the first reward variable,
wherein the first reward variable includes a skew reward variable for rewarding a skew occurring in the semiconductor device and a duty reward variable for rewarding a duty error rate of an output signal output from the semiconductor device.

2. The simulation method of claim 1, wherein the generating of the first reward variable comprises:
generating the skew reward variable; and
generating the duty reward variable, and
wherein the skew reward variable includes a first skew variable and a second skew variable, and
the duty reward variable includes a first duty variable and a second duty variable.

3. The simulation method of claim 2, wherein the generating of the skew reward variable includes summing the first skew variable and the second skew variable.

4. The simulation method of claim 2, wherein the generating of the duty reward variable includes calculating the duty reward variable based on the first duty variable and the second duty variable.

5. The simulation method of claim 4, wherein the generating of the duty reward variable includes:
calculating an error rate of each of the first duty variable and the second duty variable; and
summing an error rate of the first duty variable and an error rate of the second duty variable.

6. The simulation method of claim 1, wherein the generating of the first reward variable includes calculating the first reward variable based on a minimum value of the skew reward variable and a minimum value of the duty reward variable.

7. The simulation method of claim 1, wherein the training of the agent includes generating the first action variable by the agent based on the initial state variable and the initial reward variable.

8. A simulation device comprising:
a memory comprising instructions stored therein; and
at least one processor configured to communicate with the memory and to simulate a reinforcement learning model by executing the instructions,
wherein, responsive to executing the instructions, the at least one processor is configured:
to obtain a detected initial state variable and an initial reward variable;
to train an agent to output a first action variable of a reinforcement learning model based on the detected initial state variable and the initial reward variable; and
to generate a first state variable and a first reward variable of the reinforcement learning model based on the first action variable, and
wherein the first reward variable includes a skew reward variable that rewards skew and a duty reward variable that rewards a duty error rate.

9. The simulation device of claim 8, wherein the simulation device includes:
a current mode logic (CML) circuit including a first amplifier and a second amplifier; and
a complementary metal-oxide semiconductor (CMOS) circuit including first to sixth inverters.

10. The simulation device of claim 9, wherein at least one of the first amplifier and the second amplifier includes:
an input transistor;
a complementary input transistor;
a first transistor connected to a first node which is connected to one end of the input transistor and one end of the complementary input transistor; and
a second transistor connected to one end of the first transistor.

11. The simulation device of claim 9, wherein the second amplifier includes:
a differential input stage;
a cascode active load coupled to the differential input stage at first and second nodes, the first and second nodes forming a differential output of the second amplifier; and
a cascode bias source coupled to the differential input stage.

12. The simulation device of claim 9, wherein the CMOS circuit includes:
the first inverter connected to a first output terminal of the second amplifier;
the second inverter connected to an output terminal of the first inverter;
the third inverter connected to an output terminal of the second inverter;
the fourth inverter connected to an output terminal of the third inverter and outputting a reward variable;
the fifth inverter connected to an output terminal of the first inverter and comprising a first pair of back-to-back inverters; and
the sixth inverter connected to an output terminal of the second inverter and comprising a second pair of back-to-back inverters.

13. The simulation device of claim 8, wherein the at least one processor is configured to generate a first skew variable, a second skew variable, a first duty variable, and a second duty variable,
the skew reward variable includes the first skew variable and the second skew variable, and
the duty reward variable includes the first duty variable and the second duty variable.

14. The simulation device of claim 13, wherein the at least one processor is configured to sum the first skew variable and the second skew variable.

15. The simulation device of claim 13, wherein the at least one processor is configured to calculate the duty reward variable based on the first duty variable and the second duty variable.

16. The simulation device of claim 15, wherein the at least one processor is configured to calculate an error rate of each of the first duty variable and the second duty variable, and
sums the error rate of the first duty variable and the error rate of the second duty variable.

17. The simulation device of claim 8, wherein the at least one processor is configured to calculate the first reward variable based on a minimum value of the skew reward variable and a minimum value of the duty reward variable.

18. The simulation device of claim 8, wherein the at least one processor is configured to generate the first action variable based on the initial state variable and the initial reward variable by the agent.

19. A simulation method including a reinforcement learning model, the simulation method comprising:
obtaining detected initial state variables, initial skew reward variables, and initial duty reward variables;
training an agent to output a first action variable of a reinforcement learning model based on at least a subset of the detected initial state variables, the initial skew reward variables, and the initial duty reward variables; and
generating a first state variable, a first skew reward variable, and a first duty reward variable of the reinforcement learning model based on the first action variable,
wherein the first skew reward variable includes a first skew variable and a second skew variable, and
the first duty reward variable includes a first duty variable and a second duty variable.

20. The simulation method of claim 19, wherein the generating of the first skew reward variable includes summing the first skew variable and the second skew variable, and
the generating of the first duty reward variable includes calculating the first duty reward variable based on the first duty variable and the second duty variable.
